(19) United States
(12) Patent Application Publication
(10) Pub. No.: US 2024/0164055 A1
(43) Pub. Date: May 16, 2024

(54) FLUID MANAGEMENT SYSTEM FOR MOBILE CHARGING SYSTEM

(71) Applicant: Electric Power Systems, Inc., North Logan, UT (US)

(72) Inventors: Michael Armstrong, North Logan, UT (US); Kurt Rose, North Logan, UT (US)

(73) Assignee: Electric Power Systems, Inc., North Logan, UT (US)

(21) Appl. No.: 18/420,505

(22) Filed: Jan. 23, 2024

Related U.S. Application Data
(63) Continuation of application No. PCT/US2022/038553, filed on Jul. 27, 2022.
(60) Provisional application No. 63/226,086, filed on Jul. 27, 2021.
(60) Provisional application No. 63/244,094, filed on Sep. 14, 2021.
(60) Provisional application No. 63/244,108, filed on Sep. 14, 2021.
(60) Provisional application No. 63/313,640, filed on Feb. 24, 2022.
(60) Provisional application No. 63/313,660, filed on Feb. 24, 2022.

(51) Int. Cl. H05K 7/20; B60L 53/302; B60L 53/57; H01M 10/613; H01M 10/615; H01M 10/625; H01M 10/6568

(52) U.S. Cl. CPC H05K 7/20272; B60L 53/302; B60L 53/57; H01M 10/613; H01M 10/615; H01M 10/625; H01M 10/6568; H05K 7/20927; H01M 2220/20

(57) ABSTRACT

A mobile charging system for electric vehicles may include a fluid management system. The fluid management system may be configured to be fluidly coupled to the electric vehicle. The fluid management system may be configured to provide heating or cooling to a vehicle battery system during charging of the vehicle battery system of the electric vehicle.

### CROSS-REFERENCE TO RELATED APPLICATIONS

This application is a continuation of PCT Application PCT/US2022/038553 filed Jul. 27, 2022 and titled “FLUID MANAGEMENT SYSTEM FOR MOBILE CHARGING SYSTEM” (hereinafter the '553 application). The '553 application claims priority to, and the benefit of, Provisional Patent Application No. 63/226,086, filed Jul. 27, 2021 and titled “MOBILE MICROGRID ECOSYSTEM,” Provisional Patent Application No. 63/244,094, filed Sep. 14, 2021 and titled “MOBILE CHARGING SYSTEM WITH BI-DIRECTIONAL DC/DC CONVERTER,” Provisional Patent Application No. 63,244,108, filed Sep. 14, 2021 and titled “FLUID MANAGEMENT SYSTEM FOR MOBILE CHARGING SYSTEM,” Provisional Patent Application No. 63/313,640, filed Feb. 24, 2022 and titled “CROSS-COMPATIBLE BATTERY MODULES FOR MICROGRID SYSTEMS,” Provisional Patent Application No. 63/313,660, filed Feb. 24, 2022 and titled “COMMON BATTERY MODULES INTERFACES FOR MICROGRID SYSTEMS.” Each disclosure of the foregoing applications is incorporated herein by reference in its entireties, including but not limited to those portions that specifically appear hereinafter, but except for any subject matter disclaimers or disavowals, and except to the extent that the incorporated material is inconsistent with the express disclosure herein, in which case the language in this disclosure shall control.

### FIELD OF INVENTION

The present disclosure generally relates to apparatus, systems and methods for cross-compatible battery modules for multi-integration between mobile charging battery systems and aircraft battery systems.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may be inventions.

Charging systems often utilize a significant amount of capital, investment and fixed infrastructure. The fixed infrastructure can be limiting to operations and/or provide a high barrier to electric technology adoption. Additionally, fixed infrastructure may have limitations for charging time and adoption of improvements in the field.

### SUMMARY OF THE INVENTION

A fluid management system for a mobile charging system is disclosed herein. The fluid management system may comprise: a thermal management loop including a first heat exchanger, a first pump, a first reversing valve, and an expansion valve; a mobile portion of an electric vehicle loop, the mobile portion comprising a second pump, the mobile portion of the electric vehicle loop configured to be removably coupled to an electric vehicle to form the electric vehicle loop; and a second heat exchanger having a first port in fluid communication with the expansion valve, a second port in fluid communication with the first reversing valve, a third port in fluid communication with the second pump.

In various embodiments, the fluid management system further comprises a purge and fill system configured to fill the electric vehicle loop prior to thermally managing a vehicle battery system of the electric vehicle. The purge and fill system may comprise a third pump and a purge tank, the third pump configured to purge a fluid from the electric vehicle loop. The fluid management system may further comprise: a first fitting configured to removably couple to the electric vehicle, the first fitting in fluid communication with a fourth port of the second heat exchanger; and a second fitting configured to removably couple to the electric vehicle, the second fitting in fluid communication with the second pump. The fluid management system may further comprise a battery system of the mobile charging system, the battery system configured to charge a vehicle battery system of the electric vehicle. The fluid management system may further comprise a microgrid loop, the microgrid loop including the battery system of the mobile charging system, a third pump and a third heat exchanger. The thermal management loop may further comprise a second reversing valve, wherein: the first reversing valve is in fluid communication with the first heat exchanger, the second heat exchanger, the third heat exchanger, and the second reversing valve, and the second reversing valve is in fluid communication with the second pump and the third heat exchanger. The fluid management system may be configurable to cool the battery system of the mobile charging system and heat the vehicle battery system of the electric vehicle simultaneously.

A mobile charging system is disclosed herein. The mobile charging system may comprise: a battery system configured to charge a vehicle battery system of an electric vehicle; and a thermal management system comprising a first heat exchanger, a second heat exchanger and a third heat exchanger, the first heat exchanger in fluid communication with the second heat exchanger and the third heat exchanger through a thermal management loop, the third heat exchanger in fluid communication with the battery system through a microgrid loop, the second heat exchanger configured to be fluidly coupled to the vehicle battery system of the electric vehicle to form an electric vehicle loop.

In various embodiments, the mobile charging system further comprises a purge and fill system, the purge and fill system configured to fill the thermal management system with a working fluid prior to charging the vehicle battery system. The purge and fill system may be configured to purge the thermal management system of the working fluid after charging the vehicle battery system. The first heat exchanger may be a liquid-to-air heat exchanger, the second heat exchanger may be a first liquid-to-liquid heat exchanger, and the third heat exchanger may be a second liquid-to-liquid heat exchanger. The thermal management system may comprise a first reversing valve and a second reversing valve, the first reversing valve in fluid communication with the first heat exchanger, the second heat exchanger, the third heat exchanger and the second reversing valve. The mobile charging system may further comprise a first pump, the second reversing valve in fluid communication with the third heat exchanger and the first pump. The mobile charging system may further comprise a second pump in fluid communication with the second heat exchanger, and a third pump in fluid communication with the battery system and the third heat exchanger, the second pump configured to be fluidly coupled to the vehicle battery system of the electric vehicle. The thermal management system may be configured to cool the battery system of the mobile charging system and heat the vehicle battery system of the electric vehicle simultaneously.

A mobile charging system is disclosed herein. The mobile charging system may comprise: a battery system configured to charge a first vehicle battery system of a first electric vehicle and a second vehicle battery system of a second electric vehicle; and a thermal management system comprising a thermal management loop and a microgrid loop, the thermal management system configured to fluidly couple to the first vehicle battery system to form a first vehicle loop, the thermal management system configured to fluidly couple to the second vehicle battery system to form a second vehicle loop.

In various embodiments, the thermal management system may be configured to cool the battery system, heat the first vehicle battery system, and heat the second vehicle battery system while charging the first vehicle battery system and the second vehicle battery system. The thermal management loop may comprise a first liquid-to-air heat exchanger, an expansion valve, a second liquid-to-air heat exchanger, a plurality of liquid-to-liquid heat exchangers, a plurality of reversing valves, and heat loop pump, and a plurality of pumps. The first vehicle battery system may be configured to be fluidly coupled to a first liquid-to-liquid heat exchanger in the plurality of liquid-to-liquid heat exchangers to form the first vehicle loop. The second vehicle battery system may be configured to be coupled to a second liquid-to-liquid heat exchanger in the plurality of liquid-to-liquid heat exchangers to form the second vehicle loop. The microgrid loop may include the battery system and a third liquid-to-liquid heat exchanger in the plurality of liquid-to-liquid heat exchangers.

### BRIEF DESCRIPTION OF THE DRAWINGS

A more complete understanding of the present disclosure may be derived by referring to the detailed description and claims when considered in connection with the Figures, wherein like reference numbers refer to similar elements throughout the Figures, and where:

FIG. 1 illustrates a method of using a mobile charging ecosystem, in accordance with various embodiments;

FIG. 2 illustrates a schematic view of a mobile charging ecosystem, in accordance with various embodiments;

FIG. 3 illustrates a side view of a mobile charging ecosystem, in accordance with various embodiments;

FIG. 4 illustrates schematic view of a fluid management system of a mobile charging ecosystem, in accordance with various embodiments;

FIG. 5 illustrates schematic view of a fluid management system of a mobile charging ecosystem, in accordance with various embodiments;

FIGS. 6A, 6B, 6C, and 6D illustrate various valve configurations of a fluid management system of a mobile charging ecosystem, in accordance with various embodiments;

FIG. 7 illustrates schematic view of a fluid management system of a mobile charging ecosystem, in accordance with various embodiments; AND

FIG. 8 illustrates various valve configurations of a fluid management system of a mobile charging ecosystem, in accordance with various embodiments.

### DETAILED DESCRIPTION

The following description is of various example embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments, without departing from the scope of the appended claims. For example, the steps recited in any of the method or process descriptions may be executed in any order and are not necessarily limited to the order presented. Moreover, many of the manufacturing functions or steps may be outsourced to or performed by one or more third parties. Furthermore, any reference to singular includes plural embodiments, and any reference to more than one component or step may include a singular embodiment or step. Also, any reference to attached, fixed, connected or the like may include permanent, removable, temporary, partial, full and/or any other possible attachment option. As used herein, the terms “coupled,” “coupling,” or any other variation thereof are intended to cover a physical connection, an electrical connection, a magnetic connection, an optical connection, a communicative connection, a functional connection, and/or any other connection.

For the sake of brevity, conventional techniques for mechanical system construction, management, operation, measurement, optimization, and/or control, as well as conventional techniques for mechanical power transfer, modulation, control, and/or use, may not be described in detail herein. Furthermore, the connecting lines shown in various figures contained herein are intended to represent example functional relationships and/or physical couplings between various elements. It should be noted that many alternative or additional functional relationships or physical connections may be present in a modular structure.

A “battery array” as described herein refers to a plurality of batteries electrically coupled together. The term “array” is not meant to be limiting as to size, shape, configuration or the like. Any configuration of batteries coupled in series and/or parallel to form a battery system is within the scope of this disclosure.

In various embodiments, a charging ecosystem (e.g., for use with electric planes, drones, or the like) incorporates an air vehicle having a battery system with a battery management system (BMS) and a mobile charging system including a charger, a microgrid, a thermal management system, Internet of Things (IOT) controls, a battery management unit (BMU) token management system, and/or a unified framework for communication. In various embodiments, the thermal management system of the mobile charging system is configured to thermally manage a first battery array of the mobile charging system, a second battery array of the electric aircraft being charged, and/or any additional battery arrays (i.e., if multiple electric aircraft are being charged simultaneously). In various embodiments, thermally managing may include cooling a respective battery array or heating a respective battery array. For example, the first battery array of the mobile charging system may be cooled during operation, whereas the second battery array of the electric vehicle may be heated prior to and/or during a charging cycle and then cooled after the charging cycle, in accordance with various embodiments as disclosed further herein.

In various embodiments, the thermal management system of the mobile charging system may enable energy efficient use of both environmental and aircraft battery array thermal energy. In various embodiments, the thermal management system includes a purge and fill system configured to purge a thermal management system of an aircraft battery system prior to a fast charge cycle, purge the working fluid at the cessation of the fast charge cycle, and/or re-fill the thermal management system of the aircraft battery with a working fluid of the thermal management system of the aircraft battery system.

In various embodiments, the thermal management system includes a heat pump configured to both heat and cool an aircraft battery array and/or microgrid battery array. In this regard, the thermal management system may be configured to facilitate a fast charge cycle of the aircraft battery array while simultaneously cooling a battery array of a charging system, in accordance with various embodiments. In various embodiments, the thermal management system comprises various fluid loops configured to circulate a heat transfer fluid through at least one electric vehicle during a charging cycle, as disclosed further herein.

In various embodiments, the thermal management system further comprises a fluid loop configured to circulate the heat transfer fluid to the battery array of the charging system. In various embodiments, the thermal management system achieves high efficiency through leveraging concurrent cooling and heating of different battery zones as described further herein.

In various embodiments, a control system for the thermal management system includes a series of valves and/or liquid air heat exchangers operable through a controller. In various embodiments, the control system may further comprise sensors for consistent monitoring of temperatures throughout the system, which may be used as a feedback in the system.

In various embodiments, the thermal management system disclosed herein may minimize a reduction of battery life when direct current (DC) fast charging is used (i.e., in electric aircraft applications). In various embodiments, the thermal management system disclosed herein may help facilitate economic viability of electric aircrafts when compared to typical charging applications of electric vehicles.

In various embodiments, the thermal management system disclosed herein may facilitate on-aircraft weight reduction via the purge and fill system disclosed herein. In this regard, purging media post-charge may help reduce aircraft weight prior to take-off, in accordance with various embodiments.

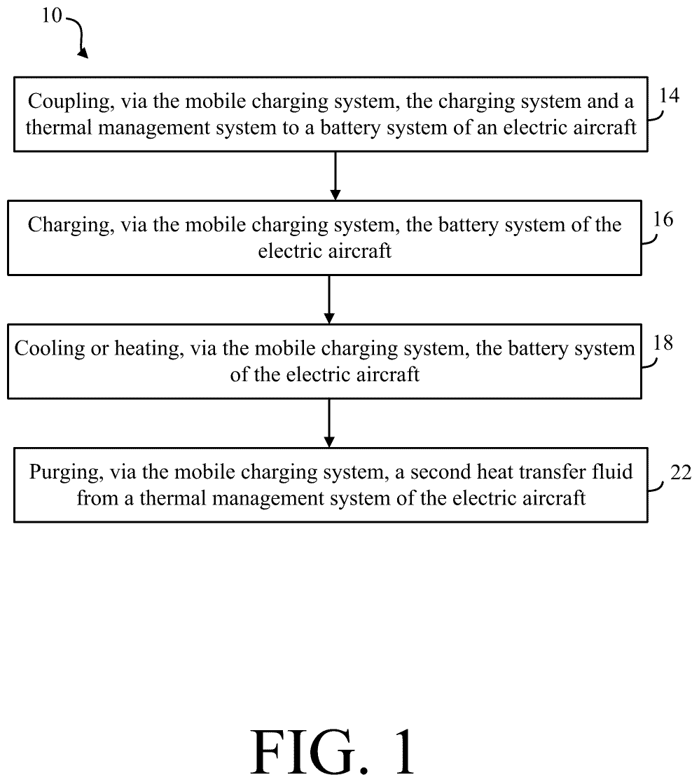

Referring now to FIG. 1, a method 10 of using thermal management system of a mobile charging system is illustrated, in accordance with various embodiments. Although described herein with respect to a mobile charging system, the present disclosure is not limited in this regard. For example, the thermal management system disclosed herein may be utilized in stationary applications, in accordance with various embodiments. The method 10 comprises coupling, via the mobile charging system, the mobile charging system and the thermal management system to a battery system of the electric aircraft (step 14). The charging system comprises a first battery array and the battery system comprises a second battery array. The first battery array is configured to charge the second battery array. In this regard, coupling the charging system to the battery system includes electrically coupling the first battery array to the second battery array. In various embodiments, the thermal management system includes a fill and purge system and a heat pump. The heat pump of the thermal management system may be configured to facilitate fast charging (i.e., heating up the second battery array during charging and/or cooling after charging) and the fill and purge system of the thermal management system may be configured to purge a heat transfer fluid from the battery system and re-fill the heat transfer fluid to maintain efficiency of the thermal management system of the electric aircraft as described further herein.

The method 10 further comprises charging, via the mobile charging system, the battery system of the electric aircraft (step 16). In various embodiments, charging the battery system may include heating, via the heat pump of the thermal management system of the mobile charging system, the second battery array prior to, or during charging (e.g., between 40° C. and 100° C., or approximately 60° C.). In various embodiments, the charging step further comprises filling (or cycling), via the mobile charging system, the thermal management system of the electric aircraft with a heat transfer fluid used to heat the battery system for fast charging as outlined above and described further herein.

In various embodiments, heating the second battery array may further comprise periodically alternating a flow direction of heat transfer fluid through the battery system for thermal balancing. In this regard, the second battery array may maintain relatively balanced temperature across all battery modules in the second battery array relative to a single direction of flow where a temperature gradient would likely occur across the battery modules.

In various embodiments, heating the battery system prior to or during charging may facilitate fast charging. For example, in various embodiments, the battery array of the battery system is heated with a fluid having a temperature at approximately 60° C. to increase lithium graphite intercalation of cells in a battery module by approximately 13 times that of typical fast charging systems and significantly reduce lithium plating. In various embodiments, the heating of the battery array with a fluid at a temperature as disclosed herein may increase a rate at which the lithium diffuses into the graphite. The rate at which the lithium diffuses into the graphite is increased approximately 6 times in typical fast charging systems. In various embodiments, the heating of the battery array with a fluid at a temperature as disclosed herein may increase an electrolyte conductivity by approximately 9 times relative to typical fast charging systems.

In various embodiments, charging the battery system may comprise discharging the first battery array of the mobile charging system with a first discharge profile. In various embodiments, the first discharge profile may have a C-rate between C/10 and C/2, or between C/8 and C/5. In various embodiments, the mobile charging system may be configured to discharge near fully over an entire day. For example, the mobile charging system may charge 5 aircraft in a day after leaving a fixed charging station and return to the fixed charging station at the end of the day, in accordance with various embodiments. In this regard, the battery system of the mobile charging system may have less wear relative to the battery system of the electric aircraft which may discharge near fully multiple times a day (i.e., through multiple flight cycles), in accordance with various embodiments. However, any suitable charge/discharge cycle times may be used.

In various embodiments, the method 10 further comprises cooling or heating, via the mobile charging system, the battery system of the electric aircraft (step 18). For example, the mobile charging system may heat the battery system of the electric aircraft during charging and cool the battery system of the electric aircraft after charging, in accordance with various embodiments. The battery system of the electric aircraft may still be in a relatively hot temperature environment prior to the cooling step from heating during charging. Thus, by cooling the battery system of the electric aircraft after fast charging, the battery system may be returned to a more efficient temperature environment for operation of the electric aircraft, in accordance with various embodiments.

In various embodiments, cooling the battery system of the electric aircraft may further comprise periodically alternating a flow direction of heat transfer fluid through the battery system for thermal balancing. In this regard, the battery system of the electric aircraft may maintain relatively balanced temperature across all battery modules in the battery system of the electric aircraft relative to a single direction of flow where a temperature gradient would likely occur across the battery modules.

In various embodiments, the method 10 further comprises purging, via the mobile charging system, the heat transfer fluid from the cooling step (e.g., step 18) from the battery system of the electric aircraft (step 22). In this regard, by purging the heat transfer fluid after a charging cycle is complete, any weight from the fluid of the thermal management system of the electric aircraft may be removed prior to flight. Thus, by utilizing a purge and fill system as disclosed herein, weight of an electric aircraft may be significantly reduced, in accordance with various embodiments.

In various embodiments, after utilizing the thermal management system of the mobile charging system in accordance with method 10, the electric aircraft may be powered via the battery system that was charged in method 10. For example, the battery system may be configured to power, via the second battery array of the battery system, the electric aircraft. In various embodiments, the second battery array may comprise a second discharge profile that is greater than the first discharge profile of the first battery array of the charging system. For example, the second battery array may comprise a second discharge profile between C/2 and 3 C or between 1 C and 2 C in accordance with various embodiments. In various embodiments, the first battery array of the charging system and the second battery array of the battery system of the electric aircraft may comprise differing charging profiles as well. For example, the first battery array of the charging system may be configured to charge over a long duration (e.g., overnight). In this regard, the first battery array of the charging system may have a charging profile between C/10 and C/5 or between C/9 and C/6, in accordance with various embodiments. In contrast, the charging rate of the second battery array of the battery system for the electric aircraft may be significantly faster than the first battery array of the charging system. For example, the charging rate of the second battery array may be between 1 C and 10 C or between 2 C and 8 C, or approximately 5 C, in accordance with various embodiments.

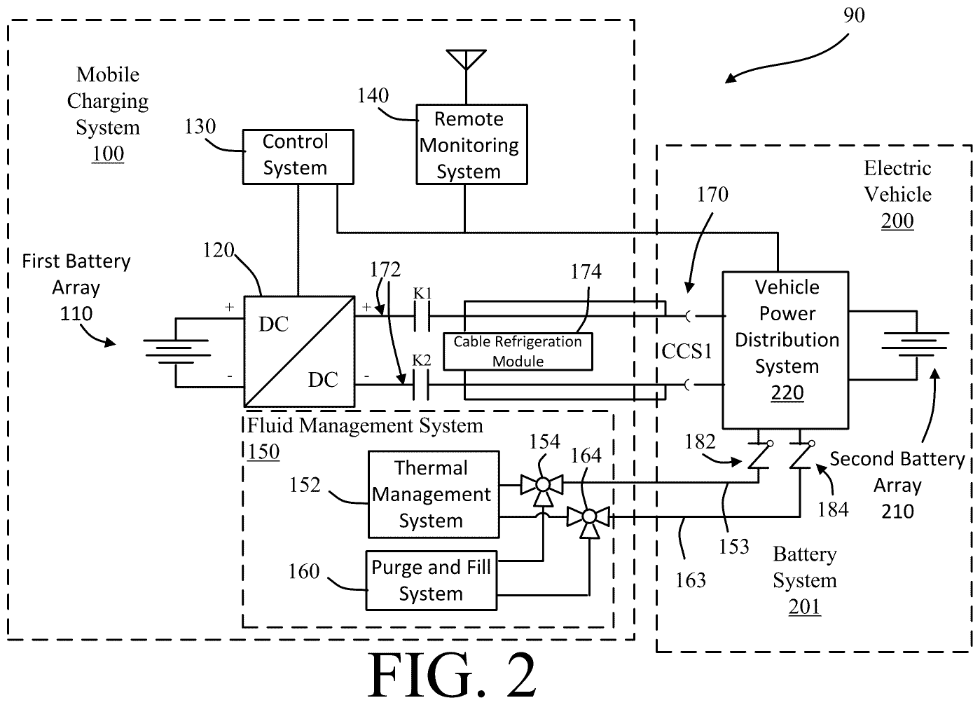

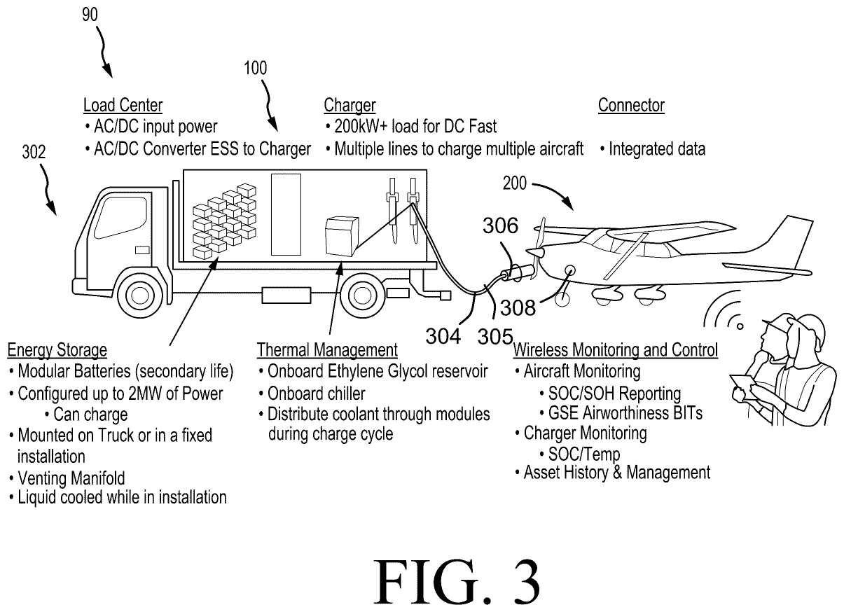

Referring now to FIGS. 2 and 3, a schematic view (FIG. 2) and a side view (FIG. 3) of an electric vehicle charging ecosystem 90 (e.g., a mobile charging ecosystem) is illustrated, in accordance with various embodiments. The electric vehicle charging ecosystem 90 may be configured for charging an electrically powered aircraft (e.g., a battery powered aircraft or the like) in accordance with method 10 from FIG. 1. The electric vehicle charging ecosystem 90 comprises a charging system 100 (e.g. a mobile microgrid and/or a mobile charging system) and an electric vehicle 200 (e.g., an electric aircraft) with a vehicle battery system 201. The charging system 100 comprises a first battery array 110. Similarly, the electric vehicle 200 comprises a second battery array 210. As described previously herein, the second battery array 210 is configured to power the electric vehicle (e.g., an electric powered aircraft or the like), in accordance with various embodiments.

In various embodiments, the charging system 100 comprises a first battery array 110, a bi-directional direct current (DC)/DC converter 120, a control system 130, a remote monitoring system 140, and/or a fluid management system 150. In an example embodiment, the fluid management system 150 comprises a thermal management system 152 and a purge and fill system 160. In various embodiments, the first battery array 110 may be configured to charge the second battery array 210 of the electric vehicle as described further herein. In various embodiments, the first battery array 110 may be configured to be charged via a fixed electrical grid (e.g., configured to receive an alternating current (AC)/DC input power) or the like prior to charging a plurality of electrical vehicles as described with respect to method 10 from FIG. 1. In various embodiments, the bi-directional DC/DC converter 120 is in operable communication with the control system 130. In this regard, the control system 130 may be configured to control charging of the second battery array 210 by the first battery array 110 through the DC/DC converter 120 and/or control charging the first battery array 110 via a fixed electrical grid through the bi-directional DC/DC converter 120 as described further herein. Although illustrated as including the bi-directional DC/DC converter 120, the present disclosure is not limited in this regard. For example, any charging configuration for the charging system 100 is within the scope of this disclosure. In various embodiments, the first battery array 110 may be mounted within a vehicle (e.g., a vehicle 302 or the like as shown in FIG. 3) or be fixedly installed on a vehicle. In various embodiments, the first battery array 110 may be a component of an energy storage system of the charging system 100. The energy storage system may include a venting manifold, in accordance with various embodiments. Although disposed within, or mounted to the vehicle 302 of FIG. 3, the first battery array 110 is not configured to power the vehicle 302. In this regard, the first battery array 110 is configured for charging an electric vehicle (e.g., electric vehicle 200) and being charged by a power grid or the like. In this regard, the first battery array 110 can be electrically isolated from a power system and/or an electrical system of the vehicle 302, in accordance with various embodiments.

In various embodiments, the electric vehicle charging ecosystem 90 comprises a combined charging system (CCS) 170 configured for high-power DC fast charging. Although illustrated as comprising a United States style combined charging system (CCS1), the charging system is not limited in this regard. For example, the combined charging system 170 may comprise a European style combined charging system (CCS2), Chademo, GBT, or any other emerging aerospace standard charging system, in accordance with various embodiments.

In various embodiments, the mobile charging system includes electrical cables 172 and a cable refrigeration module 174. The electrical cables 172 extend from the bi-directional DC/DC converter 120 to a combo plug of the combined charging system 170. The combo plug of the combined charging system 170 is configured to be electrically coupled to a socket of the combined charging system 170. In various embodiments, the combo plug is a component of the charging system 100 and the socket is a component of the electric vehicle 200 or vice versa. The present disclosure is not limited in this regard. In various embodiments, the cable refrigeration module 174 may make handling of the electrical cables 172 easier for ground personnel during charging.

In various embodiments, the cable refrigeration module 174 is configured to cool the electrical cables 172 during fast charging. For example, due to the high-power charging disclosed herein, the electrical cables may become overheated. In this regard, the cable refrigeration module 174 may be configured to maintain a safe and efficient temperature of the electrical cables 172 for efficient fast charging, in accordance with various embodiments.

In various embodiments, the bi-directional DC/DC converter 120 is configured to act as an impedance matching device. In this regard, the bi-direction DC/DC converter 120 is configured to allow power to be shuttled to and from the second battery array 210 of the vehicle battery system 201 of the electric vehicle 200, thereby enabling advanced battery state of health estimation at every charge cycle, in accordance with various embodiments. In this regard, control system 130 may be configured to estimate battery state of health and state of charge for the second battery array 210, each charge cycle. Control system 130 may further provide a certification or approval of flight worthiness for the battery at each charge cycle. In various embodiments, in response to a battery module within the second battery array reaching a useful life on the electric vehicle, the battery module may have a secondary life on the charging system 100.

After purging the working fluid, the fluid management system 150 of the charging system 100 may supply a heat transfer fluid to the battery system to heat the second battery array 210 to a predetermined temperature for fast charging as described further herein. For example, the heat transfer fluid may be configured to heat the second battery array 210 to a temperature between 40° C. and 100° C., or more preferably approximately 60° C. In various embodiments, by heating the second battery array 210 with the working fluid of the fluid management system 150 to a temperature at approximately 60° C. may increase lithium graphite intercalation of cells in a battery module by approximately 13 times that of typical fast charging systems and significantly reduce lithium plating. In various embodiments, after charging of the second battery array is completed, the purge and fill system 160 may purge any remaining heat transfer fluid from the fluid management system 150 of the charging system 100. In various embodiments, the fluid management system 150 may be configured to purge the heat transfer fluid of fluid management system 150. In various embodiments, after charging the battery system of the electric vehicle, the purge and fill system 160 may be configured to re-fill a thermal management system of the vehicle battery system 201 of the electric vehicle 200. In this regard, the purge and fill system 160 may be configured to purge a working fluid within the vehicle battery system 201 and re-fill the battery system with a new heat transfer fluid during each charge cycle for a respective electric vehicle (e.g., method 10 from FIG. 1).

In various embodiments, the fluid management system 150 comprises a thermal management system 152. In various embodiments, the thermal management system 152 and the purge and fill system 160 each connect to the vehicle via fittings 182, 184 (e.g., dripless quick-disconnect fittings or the like). In various embodiments, the thermal management system 152 and the purge and fill system 160 are isolated by using electrically controlled, three-way valves 154, 164 (i.e., only the thermal management system 152 or the purge and fill system 160 may be used at a single instance). In this regard, the thermal management system 152 and the purge and fill system 160 may be used sequentially as outlined above, in accordance with various embodiments.

In various embodiments, the control system 130 comprises a supervisory control and data acquisition system (SCADA). In this regard, the SCADA system may be configured to monitor and control processes of the charging system 100 from a remote location.

In various embodiments, the remote monitoring system 140 is in operable communication with a vehicle power distribution system 220 in response to the remote monitoring system 140 being electrically coupled to the vehicle power distribution system 220 or in response to the electric vehicle becoming in range of a wireless network of the remote monitoring system. In various embodiments, the remote monitoring system 140 comprises remote telemetry (i.e., a remote telemetry unit (RTU) with a microprocessor-based remote device configured to monitor and report events of the vehicle power distribution system 220). The remote monitoring system 140 may be configured to communicate with the vehicle power distribution system 220 of the electric vehicle through a wireless or wired connection. The present disclosure is not limited in this regard. In various embodiments, the vehicle power distribution system communicates with the remote monitoring system via a wireless network. In this regard, in response to the vehicle power distribution system becoming in range of the wireless network, the vehicle power distribution system 220 may be configured to transfer information related to operation history of the second battery array 210 to the remote monitoring system 140. In this regard, battery modules within the second battery array 210 may be continuously monitored for airworthiness, in accordance with various embodiments.

Although the fluid lines for the fluid management system 150 are illustrated separately from the electrical cables 172 and the communication lines from the control system 130, the present disclosure is not limited in this regard. For example, the plumbing lines from fluid management system 150, as well as communications connectors of the control system 130 may be integral with a connector or plug of the combined charging system 170. In this regard, in response to coupling a connector of the combined charging system 170 to the electric vehicle 200, the fittings 182, 184 may be coupled to the electric vehicle 200 and/or the control system 130 may become in operable communication with the vehicle power distribution system 220, in accordance with various embodiments. In various embodiments, the control system 130 may be in wireless communication (e.g., via Wi-Fi or a network) with the vehicle power distribution system 220 of electric vehicle 200.

In various embodiments, the vehicle power distribution system 220 is configured to distribute the power from the second battery array 210 to various electrically powered components of the electric vehicle (e.g., an electrical compressor, an electric motor, an electric fan, etc.). In this regard, an electric vehicle may be powered through the vehicle power distribution system 220 utilizing the second battery array 210 of the electric vehicle, in accordance with various embodiments. In various embodiments, the vehicle power distribution system 220 is also configured to facilitate charging of the second battery array 210 from the charging system 100.

Referring now to FIG. 3, a schematic view of the electric vehicle charging ecosystem 90 is illustrated, in accordance with various embodiments. The electric vehicle charging ecosystem 90 comprises the mobile charging system 100 and the electric vehicle 200. In various embodiments, the mobile charging system 100 comprises a vehicle 302. The vehicle 302 can comprise any type of vehicle configured to move from one location to another (e.g., a truck, a car, a motorcycle, a plane, a boat, etc.). The present disclosure is not limited in this regard. In various embodiments, the vehicle 302 comprises a motive power system (e.g., an internal combustion engine for a car, a battery system for a car, a hydrogen-powered system, a gas turbine engine for a plane, etc.) and an electrical system (e.g., configured to power electronics within the vehicle). In various embodiments, the first battery array 110 described previously herein is electrically isolated from the motive power system and the electrical system.

In various embodiments, the mobile charging system 100 further comprises a charger 304. In various embodiments, the charger 304 comprises a harness 305 and a connector 306. In various embodiments, the harness 305 is configured to house various electrical wiring (e.g., wiring to electrically couple the control system 130 to the vehicle power distribution system 220, the combined charging system 170, etc.) and/or various fluid conduits (e.g., a portion of supply line 153 and/or return line 163). In various embodiments, the connector 306 is configured to couple to a connector of the electric vehicle 200. In this regard, in response to coupling the connector 306 of the mobile charging system 100 to the connector 308 of the electric vehicle 200, the mobile charging system 100 and the electric vehicle 200 are electrically and thermally coupled in the manner shown in FIG. 2. In this regard, in response to coupling the connector 406 of the mobile charging system 100 to the connector 308 of the electric vehicle 200, the mobile charging system 100 can be configured to facilitate charging of the second battery array 210 of the electric vehicle via the first battery array 110 of the mobile charging system 100 as described previously herein.

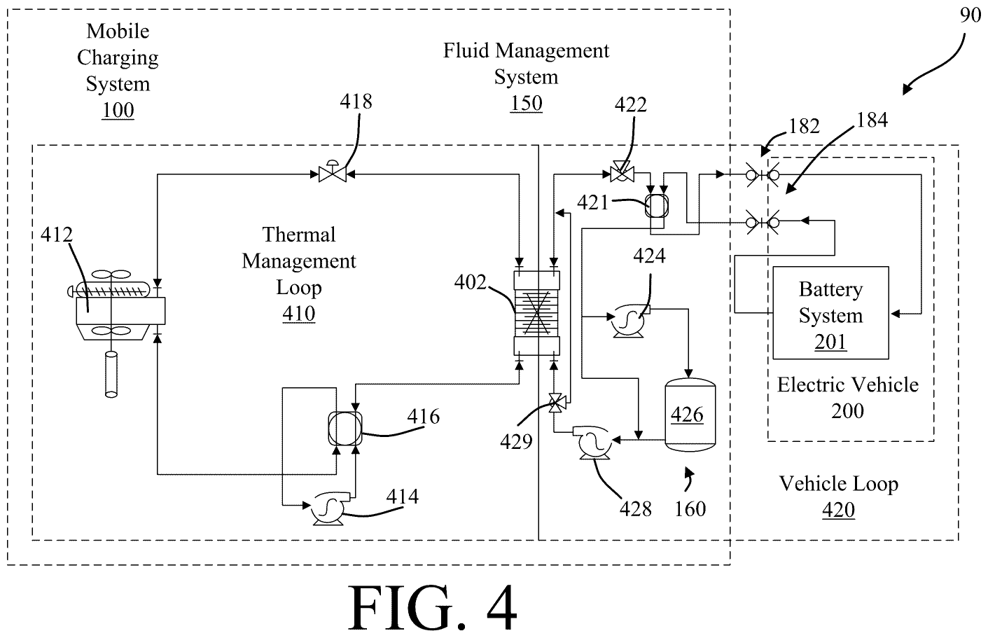

Referring now to FIG. 4, a schematic view of the fluid management system 150 of a electric vehicle charging ecosystem 90 is illustrated in accordance with various embodiments. In an operable state, the fluid management system 150 of the charging system 100 is coupled to the electric vehicle 200 of electric vehicle charging ecosystem 90 to define a thermal management loop 410 (e.g., a heat pump loop) and a vehicle loop 420. The thermal management loop 410 is disposed in the charging system 100. The vehicle loop 420 includes components disposed on the charging system 100 and the components on the electric vehicle as described further herein. The fluid management system 150 is coupled to the electric vehicle 200 via the fittings 182, 184. In this regard, the fluid management system 150 becomes fluidly coupled to the vehicle battery system 201 via the vehicle loop, in accordance with various embodiments.

The thermal management loop 410 comprises a liquid-to-air heat exchanger 412, a variable speed pump 414, a reversing valve 416, an expansion valve 418, and a liquid-to-liquid heat exchanger 402. The vehicle loop 420 comprises a purge valve 422, the fittings 182, 184, the vehicle battery system 201, a purge pump 424, a purge tank 426, a cooling pump 428, and the liquid-to-liquid heat exchanger 402. In various embodiments, the purge pump 424, the purge tank 426 and the cooling pump 428 are disposed on the charging system 100, whereas the vehicle battery system 201 is disposed on the electric vehicle 200. In this regard, in response to coupling the first fitting 182 and the second fitting 184 to the electric vehicle, the vehicle loop 420 is formed.

In various embodiments, the vehicle loop 420 comprises a reversing valve 421. The reversing valve 421 is configured to alternate a fluid flow direction through the vehicle loop 420. In this regard, during a hot charging step (e.g., step 16 of method 10 from FIG. 1) or during a cooling step (e.g., step 18 of method 10 from FIG. 1) greater thermal balancing across battery modules in the battery system 201 of the electric vehicle may be achieved relative to a single flow direction.

In various embodiments, the fluid management system 150 is configurable as a heating system for the vehicle battery system 201 for use in charging step 16 of method 10 from FIG. 1, and the fluid management system 150 is configurable as a cooling system for use in the cooling step 18 of method 10 from FIG. 1.

In a heating configuration (i.e., during step 16 of method 10), the thermal management loop 410 transfers heat from an environment surrounding the charging system 100, via the liquid-to-air heat exchanger 412 to the second battery array 210 of the vehicle battery system 201 from FIG. 2, via the liquid-to-liquid heat exchanger 402 and through the vehicle loop 420. In various embodiments, the liquid-to-liquid heat exchanger 402 is configured as a condenser of a heat pump system (e.g., fluid management system 150) in the heating configuration. In various embodiments, the liquid-to-air heat exchanger is configured as an evaporator of the heat pump system in the heating configuration.

In a cooling configuration (i.e., during step 18 of method 10), the thermal management loop 410 transfers heat from the second battery array 210 of the vehicle battery system 201 from FIG. 2, via the liquid-to-liquid heat exchanger 402 and through the vehicle loop 420, to an environment around the charging system 100, via the liquid-to-air heat exchanger 412. In various embodiments, the liquid-to-liquid heat exchanger 402 is configured as an evaporator in the cooling configuration. In various embodiments, the liquid-to-air heat exchanger 412 is configured as a condenser in the heating configuration. In various embodiments, a variable bypass valve 429 may be disposed between the cooling pump 428 and a liquid-to-liquid heat exchanger 402 and configured to deliver fluid upstream of the purge valve 422, bypassing the liquid-to-liquid heat exchanger 402, in accordance with various embodiments. In this regard, control of fluid flow through the electric vehicle 200 and temperature through the electric vehicle 200 may be controlled independently, in accordance with various embodiments.

In various embodiments, the purge and fill system 160 further comprises the purge valve 422, the purge pump 424, and the purge tank 426. The purge and fill system 160 utilizes the same vehicle connections (i.e., fittings 182, 184) as the vehicle loop 420 of the fluid management system 150 but is isolated using electrically controlled three-way valves (e.g., three-way valves 154, 164 of FIG. 2). In this regard, the fluid management system 150 is configurable in a thermal management mode (i.e., where vehicle loop 420 is in fluid communication with the thermal management system 152 as illustrated in FIG. 2). The fluid management system 150 is also configurable in a purge mode (i.e., where vehicle loop 420 is in fluid communication with the purge and fill system 160 for step 22 of method 10 from FIG. 1). The fluid management system 150 may further be configurable in a fill mode (i.e., where vehicle loop 420 is in fluid communication with the purge and fill system 160 prior to the charging step 16 of method 10 from FIG. 1). In this regard, in the fill mode, the fluid management system 150 may provide the fluid to vehicle loop 420 to be used in the heating and cooling configurations described previously herein, in accordance with various embodiments.

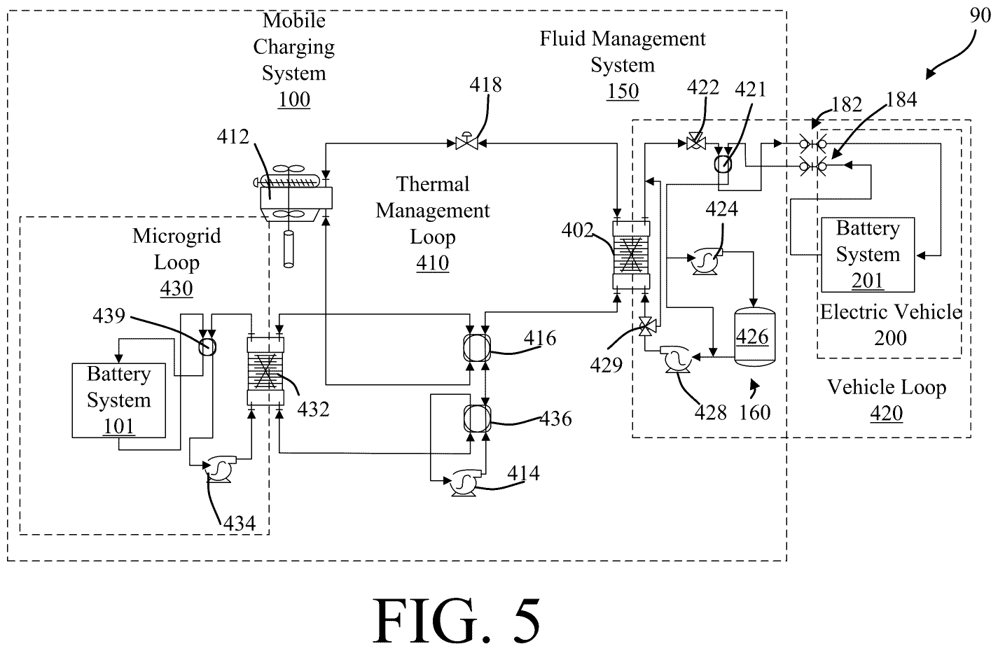

Referring now to FIG. 5, a schematic view of the fluid management system 150 further comprising a microgrid loop 430 is illustrated, in accordance with various embodiments. The microgrid loop 430 may be configured to provide heating or cooling to the battery system 101 of the charging system 100 (i.e., the battery system 101 includes the first battery array 110 from FIG. 2). The microgrid loop 430 comprises the battery system 101 of the charging system 100, a second liquid-to-liquid heat exchanger 432 and a microgrid cooling pump 434.

In various embodiments, the microgrid loop 430 comprises a reversing valve 439. The reversing valve 439 is configured to alternate a fluid flow direction through the microgrid loop 430. In this regard, during heating or cooling of the battery system 101 of the charging system 100 from FIG. 2, greater thermal balancing across battery modules in the battery system 101 of the charging system 100 from FIG. 2 may be achieved relative to a single flow direction.

In various embodiments, the thermal management loop 410 may further comprise a second reversing valve 436 disposed between the variable speed pump 414 and the reversing valve 416. The reversing valve 416 is in fluid communication with the liquid-to-liquid heat exchanger 402, the liquid-to-air heat exchanger 412, the second liquid-to-liquid heat exchanger 432, and the second reversing valve 436.

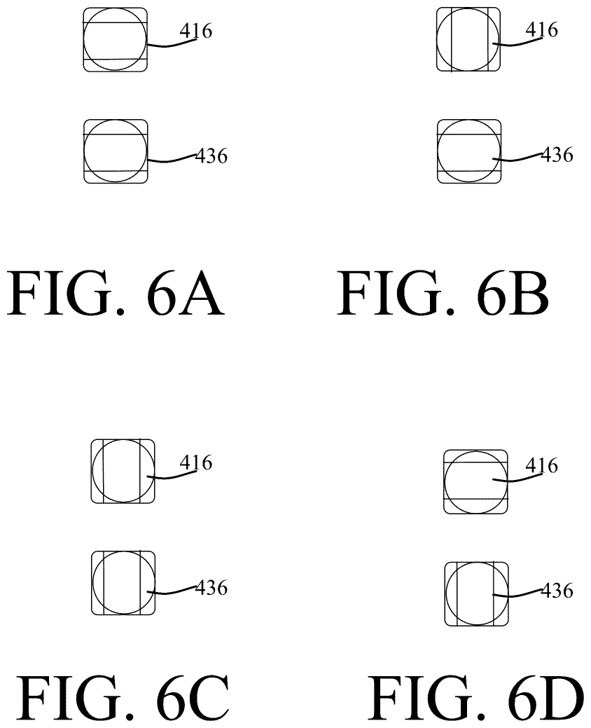

With brief reference to FIGS. 6A-6D, the reversing valves 416, 436 may be configured based on a desired configuration. For example, in a first configuration (e.g., FIG. 6A), the fluid management system 150 is configured to heat the battery system 101 of the charging system 100 and heat the vehicle battery system 201 of the electric vehicle 200. In a second configuration (e.g., FIG. 6B), the fluid management system 150 is configured to cool the vehicle battery system 201 of the electric vehicle 200 and heat the battery system 101 of the charging system 100. In a third configuration (e.g., FIG. 6C), the fluid management system 150 is configured to heat the vehicle battery system 201 of the electric vehicle 200 and cool the battery system 101 of the charging system 100. In a fourth configuration (e.g., FIG. 6D), the fluid management system 150 is configured to cool the vehicle battery system 201 of the electric vehicle 200 and cool the battery system 101 of the charging system 100.

In various embodiments, during a charging step 16 of method 10, the reversing valves 416, 436 may be oriented in accordance with FIG. 6B (i.e., configured to heat the vehicle battery system 201 of the electric vehicle 200 and cool the battery system 101 of the charging system 100). In this regard, by heating the vehicle battery system 201 of the electric vehicle 200, fast charging of the second battery array 210 from FIG. 2 may be facilitated, as described previously herein. In various embodiments, during a cooling step 18 of method 10 from FIG. 1, the reversing valves 416, 436 may be oriented in accordance with FIG. 6D (i.e., configured to cool the vehicle battery system 201 of the electric vehicle 200 and cool the battery system 101 of the charging system 100).

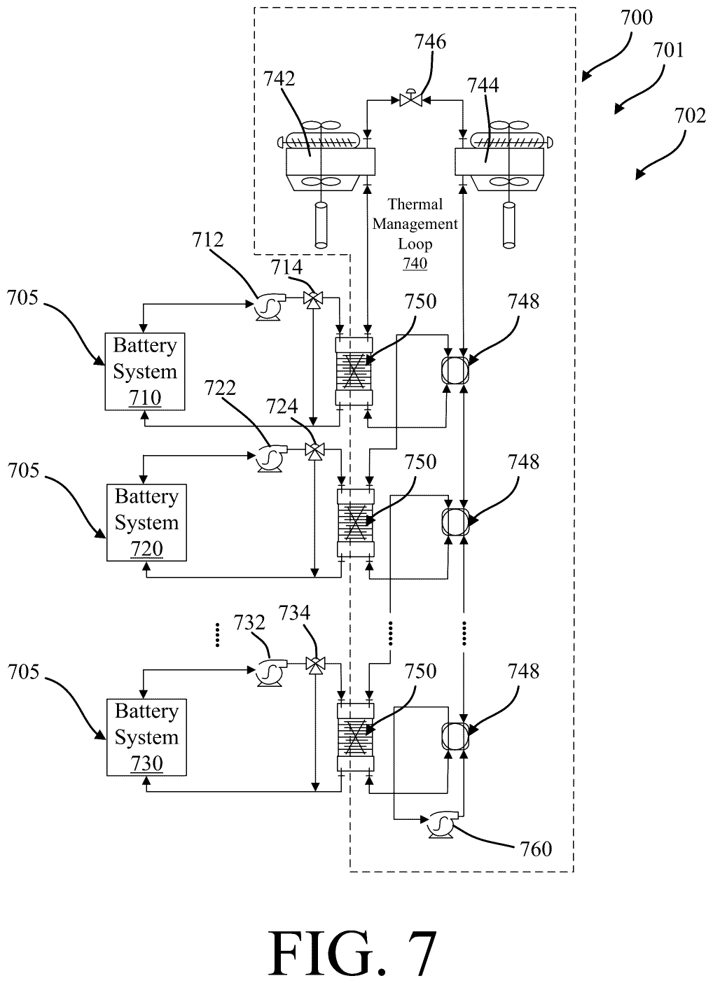

Referring now to FIG. 7, a portion of a fluid management system 700 for a mobile charging system 701 of a mobile charging ecosystem 702 is illustrated, in accordance with various embodiments. In various embodiments, the fluid management system 700 is in accordance with the fluid management system 150 except as described further herein. Similarly, the mobile charging system 701 is in accordance with the charging system 100 except as otherwise described herein and the mobile charging ecosystem 702 is in accordance with the electric vehicle charging ecosystem 90 except as described further herein. In various embodiments, the fluid management system 700 is configured for heating or cooling a plurality of battery systems 705 in a manner similar to the fluid management system 150.

In various embodiments, the plurality of battery systems 705 may comprise any number of battery systems. For example, each battery system in the plurality of battery system 705 may be in accordance with the vehicle battery system 201 of electric vehicle 200 (i.e., disposed on and configured to power the electric vehicle 200). In various embodiments, one of the battery systems in the plurality of battery systems 705 may be in accordance with the battery system 101 of the charging system 100 and a remainder of battery systems in the plurality of battery systems 705 may be in accordance with the vehicle battery system 201 of the electric vehicle 200. In this regard, the mobile charging system 701 may be configured to provide fast charging in accordance with step 16 of method 10 to multiple electric vehicles in accordance with electric vehicle 200 simultaneously, in accordance with various embodiments. Furthermore, the mobile charging system 701 may be configured to cool the battery system of the mobile charging system 701 (e.g., a first battery system 710) while heating multiple battery systems corresponding to multiple independent electric vehicles simultaneously (e.g., a second battery system 720 corresponding to a first electric aircraft and a third battery system 730 corresponding to a second electric aircraft, or the like).

In various embodiments, the plurality of battery systems 705 may be sub-systems of battery systems disclosed previously herein. For example, battery system 710 may be a first subsystem of battery system 101 of charging system 100 and battery system 720 may be a second subsystem of battery system 101 of charging system 100 from FIG. 4, in accordance with various embodiments. Similarly, battery system 710 may be a first subsystem of vehicle battery system 201 of electric vehicle 200 and battery system 720 may be a second subsystem of vehicle battery system 201 of electric vehicle 200 from FIG. 4, in accordance with various embodiments. The present disclosure is not limited in this regard.

In various embodiments, the fluid management system 700 comprises a thermal management loop 740 (e.g., a heat pump loop). The thermal management loop 740 comprises a first liquid-to-air heat exchanger 742, a second liquid-to-air heat exchanger 744, an expansion valve 746, and a plurality of reversing valves 748. In various embodiments, a number of reversing valves in the plurality of reversing valves 748 corresponds to a number of battery systems in the plurality of battery system 705. In various embodiments, the thermal management loop 740 further comprises a plurality of liquid-to-liquid heat exchangers 750. The liquid-to-liquid heat exchangers 750 may be in accordance with the liquid-to-liquid heat exchangers 402, 432. In various embodiments, a number of liquid-to-liquid heat exchangers 750 corresponds to a number of battery systems in the plurality of battery systems 705.

In various embodiments, each battery system in the plurality of battery systems comprises a cooling pump (e.g., cooling pumps 712, 722, 732). In various embodiments, the fluid management system comprises a variable speed pump 760. The variable speed pump 760 may be in accordance with the variable speed pump 414, in accordance with various embodiments. In various embodiments, as described previously herein, any of the loops may further comprise a bypass valve (e.g., bypass valve 714, 724, 734) and be configured to allow fluid to bypass a liquid-to-liquid heat exchanger 750. In this regard, the fluid management system 700 may be configured to control flow rate and temperature separately, in accordance with various embodiments. Although illustrated without reversing valve 421 from FIG. 4, the present disclosure is not limited in this regard. For example, each battery loop in the fluid management system 700 may include a reversing valve 421 from FIG. 4 to reverse a flow direction through the respective battery loop for thermal balancing as described previously herein.

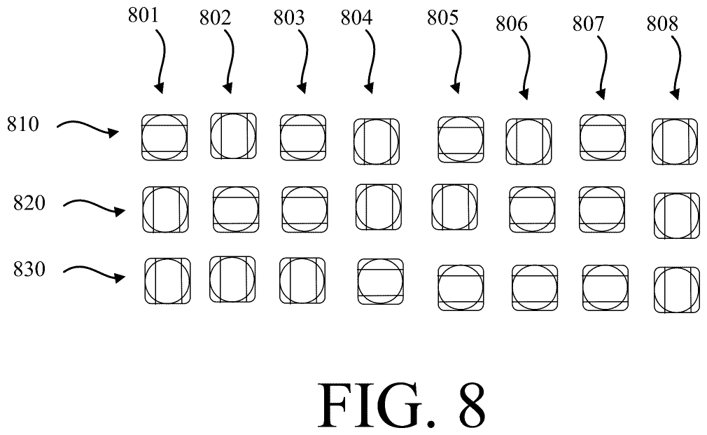

Referring now to FIG. 8, various valve configurations for a fluid management system 700 from FIG. 7 is illustrated, in accordance with various embodiments. In various embodiments, the first valves 810 represent the valve closest in proximity the reversing valve in fluid communication with the second liquid-to-air heat exchanger 744, the second valves 820 represent the reversing valve in fluid communication with the first valve 810, and the third valves 830 represent a third reversing valve that is furthest from the second liquid-to-air heat exchanger in a three battery loop system.

In various embodiments, a first configuration 801 corresponds to a heating configuration for a first battery loop corresponding to the first valve 810 and a cooling configuration for a second battery loop corresponding to the second valve 820 and a third battery loop corresponding to the third valve 830 in the battery loop system. The second configuration 802 corresponds to a heating configuration for the first battery loop and the second battery loop in the three battery loop system and a cooling configuration for the third battery loop in the three battery loop system. The third configuration 803 corresponds to a cooling configuration for the first battery loop, a heating configuration for the second battery loop corresponding to the second valve 820, and a cooling configuration for the third battery loop corresponding to the third valve 830.

In various embodiments, the fourth configuration 804 corresponds to a heating configuration for the three battery loops in the battery three battery loop system. The fifth configuration 805 corresponds to a cooling configuration for the first battery loop and a heating configuration for the second battery loop and the third battery loop. The sixth configuration 806 corresponds to a cooling configuration for the first battery loop and the second battery loop, and a heating configuration for the third battery loop. The seventh configuration 807 corresponds to a cooling configuration for the second battery loop and a heating configuration for the first battery loop and the third battery loop. The eighth configuration 808 corresponds to a cooling configuration for all three battery loops in the system. Although described with respect to a three battery loop system, any number of battery loops is within the scope of this disclosure.

While the principles of this disclosure have been shown in various embodiments, many modifications of structure, arrangements, proportions, elements, materials and components (which are particularly adapted for a specific environment and operating requirements) may be used without departing from the principles and scope of this disclosure. These and other changes or modifications are intended to be included within the scope of the present disclosure and may be expressed in the following claims.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure. Likewise, benefits, other advantages, and solutions to problems have been described above with regard to various embodiments.

However, benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

When language similar to “at least one of A, B, or C” or “at least one of A, B, and C” is used in the claims or specification, the phrase is intended to mean any of the following: (1) at least one of A; (2) at least one of B; (3) at least one of C; (4) at least one of A and at least one of B; (5) at least one of B and at least one of C; (6) at least one of A and at least one of C; or (7) at least one of A, at least one of B, and at least one of C.

We claim:

1. A fluid management system for a mobile charging system, the fluid management system comprising:
a thermal management loop including a first heat exchanger, a first pump, a first reversing valve, and an expansion valve;
a mobile portion of an electric vehicle loop, the mobile portion comprising a second pump, the mobile portion of the electric vehicle loop configured to be removably coupled to an electric vehicle to form the electric vehicle loop; and
a second heat exchanger having a first port in fluid communication with the expansion valve, a second port in fluid communication with the first reversing valve, a third port in fluid communication with the second pump.

2. The fluid management system of claim 1, further comprising a purge and fill system configured to fill the electric vehicle loop prior to thermally managing a vehicle battery system of the electric vehicle.

3. The fluid management system of claim 2, wherein the purge and fill system comprises a third pump, a purge tank, and a bypass valve, the third pump configured to purge a fluid from the electric vehicle loop, the bypass valve configured to facilitate fluid bypassing the first heat exchanger.

4. The fluid management system of claim 1, further comprising:
a first fitting configured to removably couple to the electric vehicle, the first fitting in fluid communication with a fourth port of the second heat exchanger; and
a second fitting configured to removably couple to the electric vehicle, the second fitting in fluid communication with the second pump.

5. The fluid management system of claim 1, further comprising a battery system of the mobile charging system, the battery system configured to charge a vehicle battery system of the electric vehicle.

6. The fluid management system of claim 5, further comprising a microgrid loop, the microgrid loop including the battery system of the mobile charging system, a third pump and a third heat exchanger.

7. The fluid management system of claim 6, wherein the thermal management loop further comprises a second reversing valve, wherein:
the first reversing valve is in fluid communication with the first heat exchanger, the second heat exchanger, the third heat exchanger, and the second reversing valve, and
the second reversing valve is in fluid communication with the second pump and the third heat exchanger.

8. The fluid management system of claim 6, wherein the fluid management system is configurable to cool or heat the battery system of the mobile charging system and cool or heat the vehicle battery system of the electric vehicle simultaneously.

9. The mobile charging system of claim 1, comprising:
a battery system configured to charge a vehicle battery system of the electric vehicle; and
the fluid management system further comprising a third heat exchanger, the first heat exchanger in fluid communication with the second heat exchanger and the third heat exchanger through the thermal management loop, the third heat exchanger in fluid communication with the battery system through a microgrid loop, the second heat exchanger configured to be fluidly coupled to the vehicle battery system of the electric vehicle to form the electric vehicle loop.

10. The mobile charging system of claim 9, further comprising a purge and fill system, the purge and fill system configured to fill the fluid management system with a working fluid prior to charging the vehicle battery system.

11. The mobile charging system of claim 10, wherein the purge and fill system is configured to purge the fluid management system of the working fluid after charging the vehicle battery system.

12. The mobile charging system of claim 9, wherein the first heat exchanger is a liquid-to-air heat exchanger, the second heat exchanger is a first liquid-to-liquid heat exchanger, and the third heat exchanger is a second liquid-to-liquid heat exchanger.

13. The mobile charging system of claim 9, wherein:
the fluid management system comprises a second reversing valve, and
the first reversing valve in fluid communication with the first heat exchanger, the second heat exchanger, the third heat exchanger, and the second reversing valve.

14. The mobile charging system of claim 13, wherein the second reversing valve in fluid communication with the third heat exchanger and the first pump.

15. The mobile charging system of claim 14, further comprising a third pump in fluid communication with the battery system and the third heat exchanger.

16. The mobile charging system of claim 9, wherein the fluid management system is configured to cool the battery system of the mobile charging system and heat the vehicle battery system of the electric vehicle simultaneously.

17. A mobile charging system, comprising:
a battery system configured to charge a first vehicle battery system of a first electric vehicle and a second vehicle battery system of a second electric vehicle; and
a thermal management system comprising a thermal management loop and a microgrid loop, the thermal management system configured to fluidly couple to the first vehicle battery system to form a first vehicle loop, the thermal management system configured to fluidly couple to the second vehicle battery system to form a second vehicle loop.

18. The mobile charging system of claim 17, wherein the thermal management system is configured to cool the battery system, heat the first vehicle battery system, and heat the second vehicle battery system while charging the first vehicle battery system and the second vehicle battery system.

19. The mobile charging system of claim 17, wherein the thermal management loop comprises a first liquid-to-air heat exchanger, an expansion valve, a second liquid-to-air heat exchanger, a plurality of liquid-to-liquid heat exchangers, a plurality of reversing valves, and heat loop pump, and a plurality of pumps.

20. The mobile charging system of claim 19, wherein:
the first vehicle battery system is configured to be fluidly coupled to a first liquid-to-liquid heat exchanger in the plurality of liquid-to-liquid heat exchangers to form the first vehicle loop,
the second vehicle battery system is configured to be coupled to a second liquid-to-liquid heat exchanger in the plurality of liquid-to-liquid heat exchangers to form the second vehicle loop, and
the microgrid loop includes the battery system and a third liquid-to-liquid heat exchanger in the plurality of liquid-to-liquid heat exchangers.

21. A method of thermal balancing a battery array during heating, the method comprising:
flowing a heat transfer fluid heated to a first temperature in a flow direction through the battery array from a first end of the battery array to a second end of the battery array, the battery array comprising a plurality of battery modules;
reversing the flow direction; and
flowing the heat transfer fluid heated to the first temperature in an opposite flow direction through the battery array from the second end to the first end of the battery array.

22. The method of claim 21, wherein a thermal gradient between the first end and the second end are approximately equal.

23. The method of claim 22, wherein approximately equal is plus or minus 5% of a second temperature of a first of the plurality of battery modules disposed at the first end.
